(19) United States
(12) Patent Application Publication
(10) Pub. No.: US 2008/0224315 A1
(43) Pub. Date: Sep. 18, 2008

(54) SEMICONDUCTOR DEVICE AND MANUFACTURING METHOD THEREOF

(75) Inventors: Takuji MIYATA, Ora-gun (JP); Tetsuya Yoshida, Ora-gun (JP)

Correspondence Address: MORRISON & FOERSTER LLP, 1650 TYSONS BOULEVARD, SUITE 400, MCLEAN, VA, 22102, US

(73) Assignees: SANYO ELECTRIC CO., LTD., Moriguchi-shi (JP); SANYO SEMICONDUCTOR CO., LTD., Ora-gun (JP)

(21) Appl. No.: 12/045,998

(22) Filed: Mar. 11, 2008

(30) Foreign Application Priority Data
Mar. 14, 2007 (JP) 2007-065355

(51) Int. Cl. H01L 23/52; H01L 21/50

(52) U.S. Cl. 257/750; 438/113; 257/E23.141; 257/E21.499

(57) ABSTRACT

In a semiconductor device having a bonding wireless structure, a preform material is used for electrically connecting a metal plate serving as a connection with an electrode layer of a semiconductor chip. Thus, a multilayered metal layer needs to be provided in a junction part between the preform material and a first electrode layer, but has a problem of a variation in electrical characteristics and characteristic fluctuations in a temperature cycling test and the like. A metal layer mainly made of titanium is formed with a thickness of 1000 Å, as a bottom layer (a first metal layer in contact with an electrode layer of a semiconductor chip) in a multilayered metal layer with an electron impact heating deposition method. Thus, the film quality of the Ti layer is improved compared with the conventional structure, which minimizes variations in electrical characteristics and characteristic fluctuations in the multilayered metal layer.

### BACKGROUND OF THE INVENTION

This application claims priority from Japanese Patent Application Number JP2007-065355 filed on Mar. 14, 2007, the content of which is incorporated herein by reference in its entirety.

1. Field of the Invention

The present invention relates to a semiconductor device and a manufacturing method thereof, and more particularly relates to a semiconductor device having improved reliability of a junction part between a semiconductor chip and a preform material in a wireless structure.

2. Description of the Related Art

There has been known a semiconductor device having a so-called bonding wireless structure in which thin metal wires (bonding wires) are not used as connection for leading an electrode on a semiconductor chip to the outside. This technology is described for instance in Japanese Patent Application Publication No. 2003-229460.

FIGS. 11A to 11C show an example of a conventional semiconductor device having a bonding wireless structure (hereinafter referred to as a wireless structure). FIG. 11A is a plan view, FIG. 11B is a cross-sectional view along the line b-b in FIG. 11A, and FIG. 11C is an enlarged cross-sectional view of an electrode portion. Note that a resin layer is omitted in each of FIGS. 11A and 11C.

As shown in FIGS. 11A and 11B, a semiconductor chip 201 is, for example, a MOSFET (Metal Oxide Semiconductor Field Effect Transistor), a diode, a bipolar transistor or the like. Here, description will be given of the case where the MOSFET is used as an example. A surface electrode 202 made of aluminum alloy or the like is provided on one of principal surfaces (called a first principal surface) of the semiconductor chip 201. A lead frame 220 is a punching frame made of copper. On a header 221 of this frame, the semiconductor chip 201 is fixed by use of a preform material 204 made of, for example, solder or Ag paste. On the other principal surface of the semiconductor chip 201, a back surface electrode 205 is formed by use of a lining metal layer. A lead 225 connected to the header 221 is led to the outside as a drain terminal.

On the surface electrode 202, a multilayered metal layer 203 made of Ti, Ni, Cu and Au is provided to improve adhesion between the surface electrode 202 and the preform material (for example, solder) 204 while reducing resistance therebetween. Moreover, a metal plate 227 is fixed above the surface electrode 202 by the preform material 204. The metal plate 227 is led to the outside as a source terminal. Moreover, similarly, a metal plate 226 is fixed on the first principal surface side and led to the outside as a gate terminal.

The semiconductor chip 201, the lead frame 220 and the metal plates 226 and 227 are resin-sealed by transfer molding using a mold, and a resin layer 208 forms an external shape of a package.

As shown in FIG. 11C, the multilayered metal layer 203 is formed on the surface electrode (Al layer) 202. The multilayered metal layer 203 is formed by continuously depositing a titanium (Ti) layer 203a, a nickel (Ni) layer 203b, a copper (Cu) layer 203c and a gold (Au) layer 203d in this order from a lower layer (the surface electrode 202) side. The Ti layer 203a is formed to have a thickness of, for example, 100 Å by use of an electron impact heating deposition method, the Ni layer 203b is formed to have a thickness of, for example, 200 Å by use of the electron impact heating deposition method, the Cu layer 203c is formed to have a thickness of, for example, 1500 Å by use of a resistance heating deposition method, and the Au layer 203d is formed to have a thickness of, for example, 625 Å by use of the resistance heating deposition method.

Any semiconductor devices having a wireless structure described above, regardless of the kind of a semiconductor chip (a MOSFET, a bipolar transistor, a diode, an IGBT (Insulated Gate Bipolar Transistor) or the like), are frequently subjected to defects such as variations in electrical characteristics (for example, forward voltage characteristics and forward current), poor on-resistance, and characteristic fluctuations before and after a temperature cycling test.

As a result of an experiment, the following is found out. Specifically, the variations in electrical characteristics are caused by a variation in a resistance value of the multilayered metal layer 203 serving as a junction part between the semiconductor chip 201 and the preform material 204 (solder). Moreover, the characteristic fluctuations are caused by a stress fluctuation in the multilayered metal layer 203 before and after the temperature cycling test

The variations in electrical characteristics attributable to the variation in the resistance value have a problem of causing reduction in yield. Moreover, the characteristic fluctuations attributable to the stress have a problem of leading to reduction in reliability due to not only reduction in bonding strength but also, for example, fluctuations in initial characteristics such as the forward voltage characteristics.

### SUMMARY OF THE INVENTION

The invention provides a semiconductor device that includes a semiconductor chip, an electrode layer disposed on the chip, a multilayered metal layer disposed on the electrode layer, a connection formed of a metal plate and disposed on the multilayered metal layer, and a layer of a preform material attaching the connection to the multilayered metal layer, wherein the multilayered metal layer is formed by laminating a first metal layer comprising titanium and having a thickness of 400 Å to 2000 Å, a second metal layer comprising nickel and having a thickness of 100 Å to 1000 Å and a third metal layer comprising copper or chromium and having a thickness of 500 Å to 2000 Å in this order.

### BRIEF DESCRIPTION OF THE DRAWINGS

FIG. 1A is a perspective view and FIGS. 1B and 1C are cross-sectional views showing a semiconductor device according to an embodiment of the present invention.

FIG. 2 is a factorial effect diagram for explaining the semiconductor device according to the embodiment of the present invention.

FIG. 3 is a characteristic diagram for explaining the semiconductor device according to the embodiment of the present invention.

FIG. 4 is a characteristic diagram for explaining the semiconductor device according to the embodiment of the present invention.

FIG. 5 is a characteristic diagram for explaining the semiconductor device according to the embodiment of the present invention.

FIGS. 6A to 6C show results of Auger analysis on the semiconductor device according to the embodiment of the present invention.

FIG. 7 is a cross-sectional view showing a method for manufacturing a semiconductor device according to an embodiment of the present invention.

FIGS. 8A to 8D are cross-sectional views showing the method for manufacturing a semiconductor device according to the embodiment of the present invention.

FIG. 9 is a cross-sectional view showing the method for manufacturing a semiconductor device according to the embodiment of the present invention.

FIGS. 10A and 10B are cross-sectional views showing the method for manufacturing a semiconductor device according to the embodiment of the present invention.

FIG. 11A is a plan view and FIGS. 11B and 11C are cross-sectional views showing a conventional semiconductor device.

### DESCRIPTION OF THE EMBODIMENTS

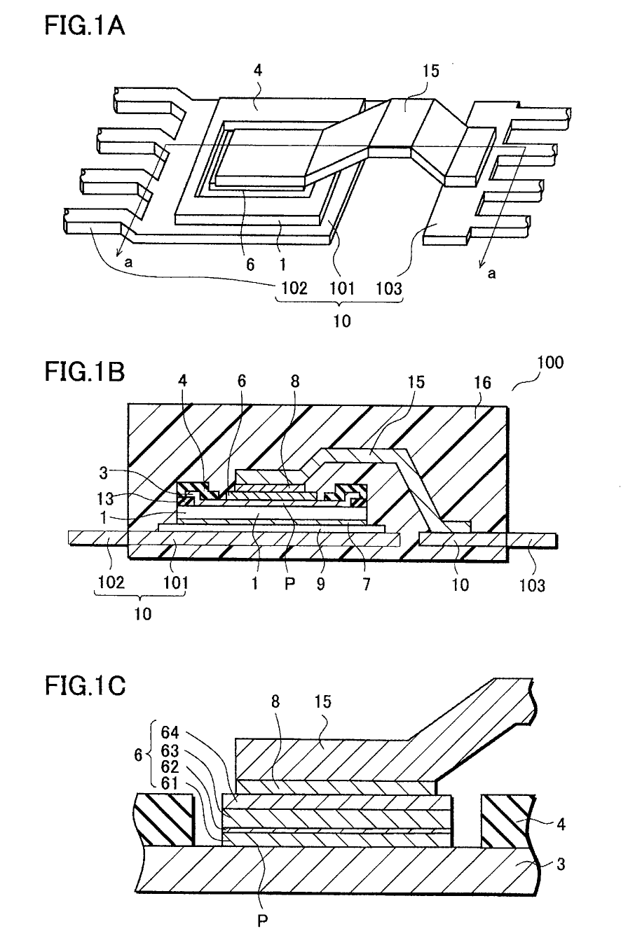

With reference to FIGS. 1 to 10, a semiconductor device of the present invention will be described by taking a Schottky barrier diode (hereinafter referred to as a SBD) as an example.

FIGS. 1A to 1C show an example of a semiconductor device 100. FIG. 1A is a perspective view, FIG. 1B is a cross-sectional view along the line a-a in FIG. 1A, and FIG. 1C is an enlarged cross-sectional view of an electrode portion. Note that a resin layer is omitted in each of FIGS. 1A and 1C.

A semiconductor device 100 of the present invention includes a semiconductor chip 1, a multilayered metal layer 6, a preform material 8 and a connection 15.

As shown in FIGS. 1A and 1B, the semiconductor chip 1 is, for example, a SBD in which an n− type semiconductor layer is laminated on an n+ type semiconductor substrate and a Schottky metal layer (for example, titanium (Ti), molybdenum (Mo) or the like) which forms a Schottky junction with a surface of the n− type semiconductor layer is provided.

On the first principal surface of the semiconductor substrate, a first electrode layer 3 is provided. The first electrode layer 3 is an anode electrode provided on the Schottky metal layer (not shown here). The first electrode layer 3 is, for example, an aluminum (Al) layer or an aluminum layer containing silicon (Si) with a thickness of about 2 μm to 3 μm.

Moreover, on the other principal surface of the semiconductor substrate, a second electrode (lining electrode) layer 7 is provided by metal evaporation. The second electrode layer 7 is, for example, a Ti-nickel (Ni)-gold (Au) layer (500 Å-5000 Å-500 Å in thickness, respectively). Here, the second electrode layer 7 serves as a cathode electrode.

On the first electrode layer 3, for example, an insulating film 4 such as a nitride film is provided. An opening is provided at a desired position in the insulating film 4. The first electrode layer 3 exposed from the opening in the insulating film 4 serves as a pad portion P.

As shown in FIG. 1C, the multilayered metal layer 6 is provided on the pad portion P of the first electrode layer 3 and is formed by laminating, from the bottom (the first electrode layer 3 side), a first metal layer 61 mainly made of Ti, a second metal layer 62 mainly made of Ni, a third metal layer 63 made of copper (Cu) or chromium (Cr) and a fourth metal layer 64 made of gold (Au), palladium (Pd) or platinum (Pt).

The semiconductor chip 1 is mounted on a supporting substrate 10. The supporting substrate is, for example, a lead frame 10. The lead frame 10 is a punching frame made of copper which has a cathode terminal 102 and an anode terminal 103. On a header 101 of this frame, the semiconductor chip (bare chip) 1 as the SBD is fixed by use of a preform material 9 made of solder or Ag paste. Thus, the second electrode layer 7 of the SBD is electrically connected to the cathode terminal 102.

As shown in FIGS. 1B and 1C, the preform material 8 is applied to a surface of the multilayered metal layer 6 (the fourth metal layer 64) and the connection 15 made of a Cu metal plate or the like, for example, is fixed thereto.

The preform material 8 is solder (a lead (Pb)/tin (Sn) layer) or lead-free solder (for example, silver (Ag)/Sn layer, a Ag/Cu layer or a Ag/Au layer).

The connection 15 is connected to the lead frame 10 having the anode terminal 103 and electrically connects the first electrode layer (the anode electrode) 3 to the anode terminal 103. Note that the connection 15 may be directly extended to be led to the outside as the anode terminal 103.

The semiconductor chip 1 as the SBD, the lead frame 10 and the connection 15 are resin-sealed by transfer molding using a mold, and a resin layer 16 forms an external shape of a package.

As described above, in the semiconductor device 100 having a wireless structure that achieves electrical connection by use of the metal plate such as the connection 15 without using a bonding wire for connection between the semiconductor chip 1 and the lead frame 10, resistance of the bonding wire itself is not added to resistance of the semiconductor chip. Thus, a semiconductor device with a small loss which does not interfere with element characteristics can be achieved.

Meanwhile, when the connection 15 is connected to the first electrode layer 3, it is required to use the preform material 8 such as solder. Moreover, in order to secure bonding properties between the preform material 8 and the first electrode layer 3 and to prevent erosion, the multilayered metal layer 6 made of desired metal is required to be provided on the first electrode layer 3.

With reference to FIG. 1C, the multilayered metal layer of this embodiment will be described in detail.

In the multilayered metal layer 6, the metal layer mainly made of Ti is provided as the first metal layer 61 on the bottom (the first electrode layer 3 side) in order to enhance adhesion with the Al layer that is the first electrode layer 3. The metal layer mainly made of Ti is a Ti (pure Ti) layer or a boron (B)-containing Ti layer. The first metal layer 61 is formed by use of an electron impact heating deposition method so as to have a thickness of 400 Å to 2000 Å (for example, 1000 Å).

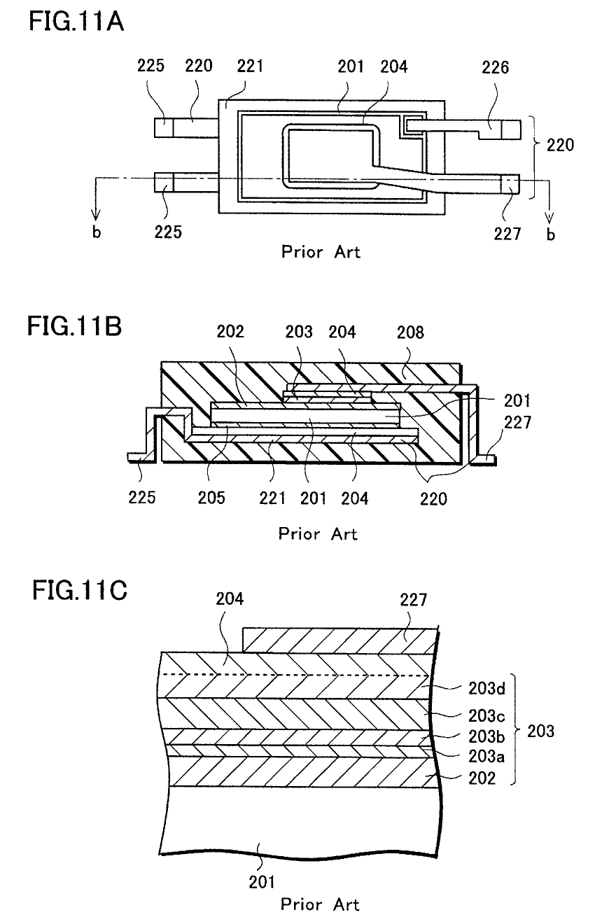

For the first metal layer 61 in this embodiment, the thickness about 10 times larger than that of the first metal layer 203a (see FIG. 11C) in the conventional structure is adopted. A good film formation state of the first metal layer 61 can be achieved by increasing the thickness. Accordingly, it is possible to reduce a variation in a resistance value in the multilayered metal layer 6 serving as a junction part between the first electrode layer 3 on the semiconductor chip 1 and the preform material 8. Thus, a variation in electrical characteristics of the semiconductor device 100 can be minimized.

Moreover, by forming the first metal layer 61 so as to have a large thickness, stress in the multilayered metal layer 6 can also be reduced. Thus, reliability can be improved by minimizing fluctuations in characteristics (for example, forward voltage characteristics) before and after a temperature cycling test for the semiconductor device 100, for example.

On the first metal layer 61, the metal layer mainly made of Ni is provided as the second metal layer 62 in consideration of prevention of invasion (erosion) by the preform material 8 and in consideration of bonding properties with respect to the preform material 8. This metal layer is a Ni (pure Ni) layer, a phosphorus (P)-containing Ni layer or a B-containing Ni layer. The second metal layer 62 is formed by use of the electron impact heating deposition method so as to have a thickness of 100 Å to 1000 Å (for example, 200 Å).

On the second metal layer 62, a Cu layer or a Cr layer is provided as the third metal layer 63 in consideration of, for example, suppression of spread of the preform material 8, prevention of invasion by the preform material 8, and the bonding properties. The third metal layer 63 is formed by use of a resistance heating deposition method so as to have a thickness of 500 Å to 2000 Å (for example, 1500 Å).

On the third metal layer 63, the metal layer is provided as the fourth metal layer 64, which improves wettability and bonding properties with respect to the preform material 8 and which prevents oxidation of the third metal layer 63. The fourth metal layer 64 is an Au layer, a Pd layer or a Pt layer formed by use of the resistance heating deposition method and has a thickness of 600 Å to 2000 Å (for example, 1000 Å).

In this embodiment, the thicknesses of the first to fourth metal layers 61 to 64 described above are determined by evaluating reproducibility of optimum values selected by conducting an experiment using a L9 orthogonal table (Taguchi method) in which the respective metal layers are set as factors and the thickness of each of the factors is set as a level value. This will be described below.

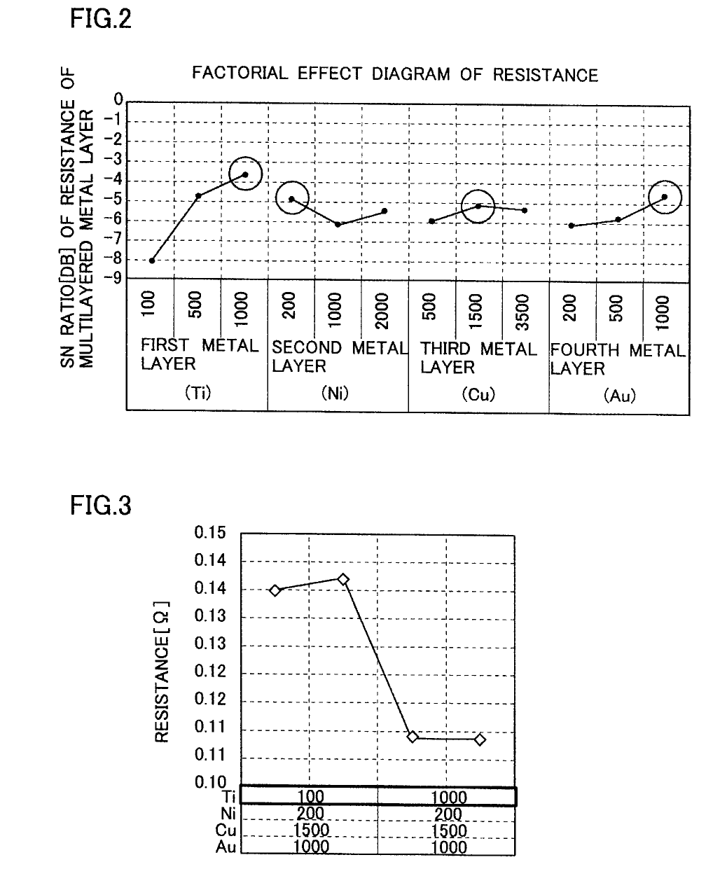

First, FIG. 2 shows results of the experiment using the Taguchi method for selecting the thickness of the multilayered metal layer 6 in this embodiment.

FIG. 2 is a factorial effect diagram for resistance in the case where an experiment is conducted by use of a 3-level (L9) orthogonal table for a resistance value of the multilayered metal layer 6. A vertical axis represents an SN ratio [dB] of resistance and a horizontal axis represents the thicknesses of the first to fourth metal layers 61 to 64. Moreover, the resistance value of the multilayered metal layer 6 corresponds to resistance values of the first to fourth metal layers 61 to 64 in a lamination direction thereof.

In this case, the SN ratio close to 0 dB is desirable. Moreover, as shown in FIG. 2, a factorial effect amount (amount of change) of the first metal layer (Ti layer) 61 is greater than those of the other layers. FIG. 2 shows that, in the configuration of the multilayered metal layer 6 in this embodiment, particularly, an increase in the thickness of the first metal layer (Ti layer) 61 contributes to minimization of a variation in the resistance value of the multilayered metal layer 6.

Therefore, in this embodiment, the thickness of the first metal layer 61 is set to 400 Å to 2000 Å (for example, 1000 Å), which is larger than that (100 Å) in the conventional structure. Moreover, the thickness of the second metal layer (Ni layer) 62 is set to 100 Å to 1000 Å (for example, 200 Å). The thickness of the third metal layer (Cu layer) 63 is set to 500 Å to 2000 Å (for example, 1500 Å). The thickness of the fourth metal layer (Au layer) 64 is set to 600 Å to 2000 Å (for example, 1000 Å).

Next, description will be given of results obtained by verifying reproducibility of the thicknesses of the respective metal layers.

FIG. 3 shows a relationship between the thickness of the first metal layer (Ti layer) 61 and the resistance value of the multilayered metal layer 6 in its lamination direction.

FIG. 3 shows results obtained by measuring resistance values [Ω] (vertical axis) of a plurality of multilayered metal layers 6 (horizontal axis) which are different from each other in the thickness of the first metal layer (Ti layer) 61. As to the first metal layer (Ti layer), a comparison is made between the thickness of 100 Å equal to that in the conventional structure and the thickness of 1000 Å that is 10 times larger than that in the conventional structure. It is noted that two data points were obtained from two different manufacturing lots for each of the two thicknesses of the Ti layer. Generally, the resistance values of the metal layers tend to be increased as the thicknesses thereof in the lamination direction are increased. But, it is found out that the resistance value itself is lower in the case where the thickness of the first metal layer (Ti layer) 61 is 1000 Å than in the case where the thickness thereof is 100 Å. The drastic decrease shown in FIG. 3 was not expected and were not known in the art to the best knowledge of the inventors of this application.

This is considered to be because, in the case where the first metal layer (Ti layer) 61 has a thickness of 1000 Å, a natural oxide film (about 10 Å to 50 Å) in the first electrode layer (Al layer) therebelow can be sufficiently reduced and thus the first metal layer can sufficiently react with the second metal layer (Ni layer) 62 thereabove.

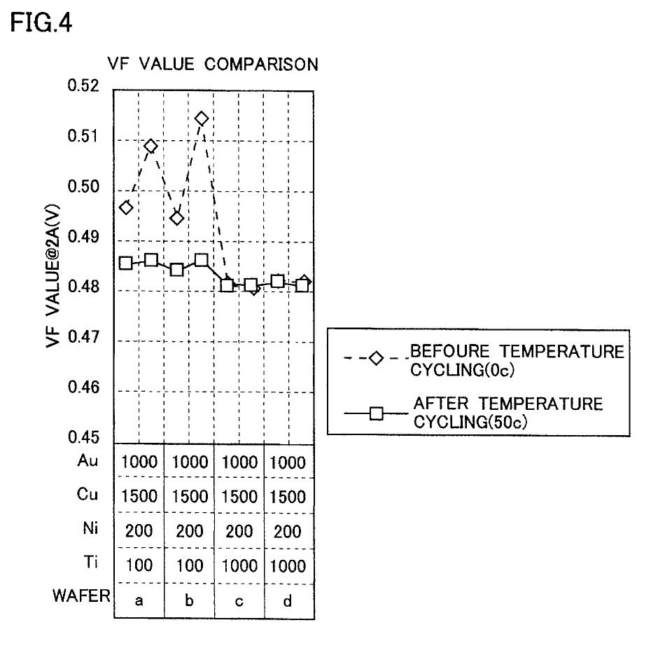

FIG. 4 shows a relationship between the thickness of the first metal layer (Ti layer) 61 and forward voltage characteristics before and after a temperature cycling test. FIG. 4 shows results obtained by measuring forward voltage VF values at 2.0 A for a plurality of wafers (horizontal axis) having the multilayered metal layers 6, which are different from each other in the thickness of the first metal layer (Ti layer) 61. It is noted that two data points were obtained for each of the wafers a-d by measuring different devices on the wafers. In each of wafers a and b, the thickness of the first metal layer 61 is set to 100 Å. In each of wafers c and d, the thickness of the first metal layer 61 is set to 1000 Å.

Moreover, a broken line indicates a forward voltage VF value before the temperature cycling test and a solid line indicates a forward voltage VF value after the temperature cycling test. The temperature cycling test is conducted for 50 cycles at ambient temperature Ta=−55° C. to 125° C. Moreover, the forward voltage VF values are results of measurement on the semiconductor device 100 shown in FIG. 1.

As shown in FIG. 4, in the case where the thickness of the first metal layer (Ti layer) 61 is 100 Å (the wafers a and b), the forward voltage VF value significantly fluctuates before and after the temperature cycling test. On the other hand, in the case where the thickness of the first metal layer 61 is 1000 Å (the wafers c and d), the forward voltage VF value hardly fluctuates before and after the temperature cycling test.

No characteristic fluctuation in the temperature cycling test means high resistance to thermal stress. Thus, reliability in the portion of the multilayered metal layer 6 (and the first electrode layer 3) can be improved.

In this case, the thicknesses of the second metal layer (Ni layer) 62, the third metal layer (Cu layer) 63 and the fourth metal layer (Au layer) 64 are set to 200 Å, 1500 Å and 1000 Å, respectively, and are set the same among the multilayered metal layers 6 (the wafers a to d). Specifically, the characteristic fluctuations in the temperature cycling test can be minimized only by increasing the thickness of the first metal layer (Ti layer) 61 (about 1000 Å). Thus, stress relaxation in the portion of the multilayered metal layer 6 and the first electrode layer 3 can be realized.

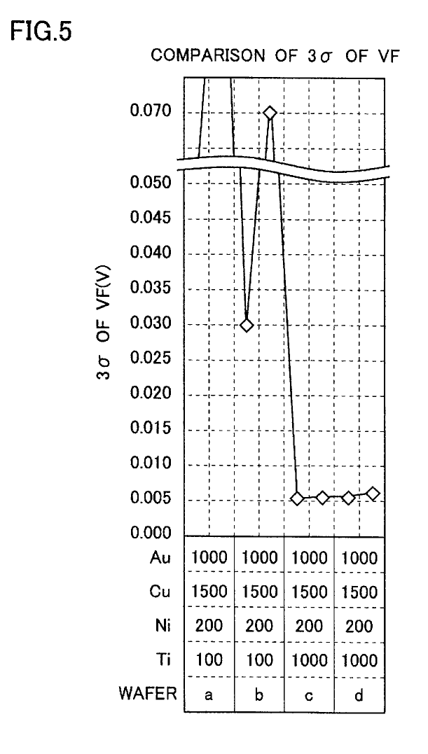

Next, with reference to FIG. 5, description will be given of a relationship between the thickness of the first metal layer (Ti layer) 61 and a forward voltage variation.

FIG. 5 shows results when 3σ (3 times larger than the standard deviation σ) is obtained as the forward voltage variation for a plurality of multilayered metal layers 6 (horizontal axis), which are different from each other in the thickness of the first metal layer (Ti layer) 61. The wafers a to d are the same as those in the case of FIG. 4 and two data points were obtained for each of the wafers a-d by measuring different devices on the wafers.

As shown in FIG. 5, in the case where the thickness of the first metal layer (Ti layer) 61 is 100 Å (for example, the wafer b), 3σ of the forward voltage is 0.071. On the other hand, in the case where the thickness of the first metal layer 61 is 1000 Å (the wafers c and d), 3σ of the forward voltage is 0.006. Thus, 3σ is reduced by 90% (down to 10%).

Also in this case, the thicknesses of the second metal layer (Ni layer) 62, the third metal layer (Cu layer) 63 and the fourth metal layer (Au layer) 64 are set the same among the multilayered metal layers 6 (the wafers a to d). Specifically, the variation (3σ) in the forward voltage can be significantly reduced by 90% only by increasing the thickness of the first metal layer (Ti layer) 61 (about 1000 Å).

Next, the thickness of the fourth metal layer (Au layer) 64 will be described. With reference to the factorial effect diagram shown in FIG. 2, it is desirable that the fourth metal layer (Au layer) 64 also has a large thickness. In this embodiment, the thickness thereof is set to 600 Å to 2000 Å (for example, 1000 Å).

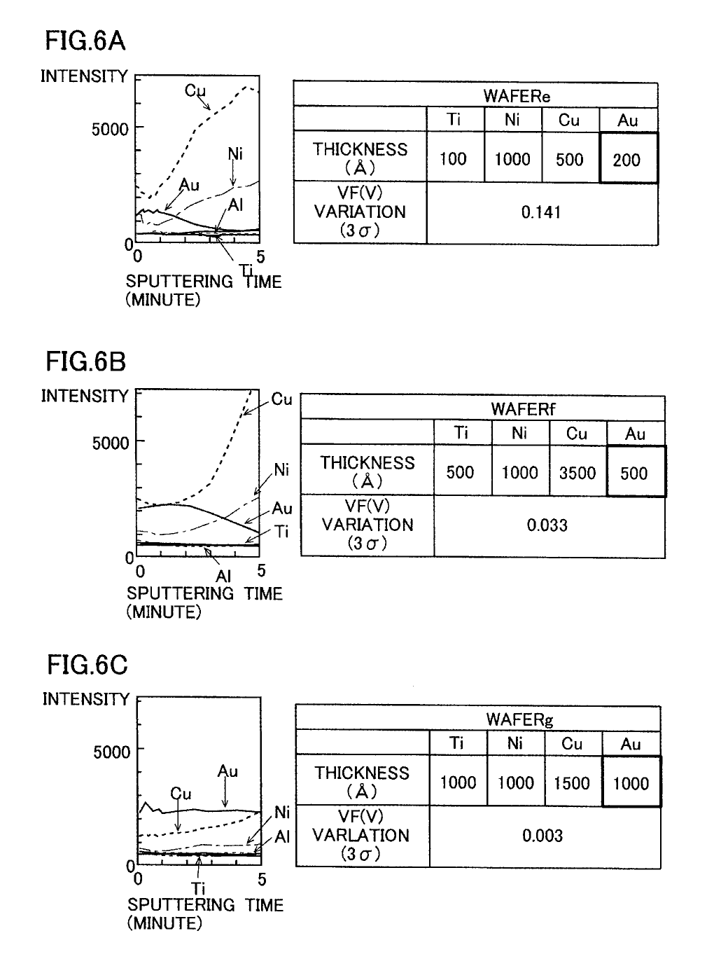

FIGS. 6A to 6C show results of analysis (Auger analysis) on the multilayered metal layers 6 by use of an Auger electron spectroscopy analyzer for wafers e to g having the multilayered metal layers 6, which are different from each other in the configuration of the first to fourth metal layers 61 to 64.

FIG. 6A shows an analysis result for the wafer e in which the fourth metal layer (Au layer) 64 has a thickness of 200 Å. FIG. 6B shows an analysis result for the wafer f in which the fourth metal layer (Au layer) 64 has a thickness of 500 Å. FIG. 6C shows an analysis result for the wafer g in which the fourth metal layer (Au layer) 64 has a thickness of 1000 Å.

Moreover, measurement is made in a state where the multilayered metal layer 6 is formed on the first principal surface of each of the wafers and, thereafter, a second electrode (lining electrode) layer 7 is provided on the other principal surface thereof. Each of FIGS. 6A to 6C also shows a result of a variation (3σ) in a forward voltage measured when a semiconductor chip extracted from each of the wafers is mounted.

Note that the wafers e to g are different from each other in the configuration (thickness) of the first to third metal layers 61 to 63. However, since examination is made on the fourth metal layer 64 to be the top surface in the wafer state, there is not much influence of the difference in the thicknesses of the metal layers therebelow.

An Auger electron spectroscopy is an extreme surface element analysis method for finding out constituent elements by use of electrons (Auger electrons) specific to elements released from a sample surface when the sample surface is irradiated with electron beams. In each of FIGS. 6A to 6C, a vertical axis represents an amount of elements released (intensity) in each of the metal layers and a horizontal axis represents sputtering time. Specifically, the position where the sputtering time is 0 indicates presence of constituent elements on the top surface of each wafer (the multilayered metal layer 6). Moreover, as the sputtering time passes by, constituent elements in the lower layers appear.

As shown in FIG. 6A, it is found out that, in the case where the fourth metal layer 64 has a small thickness (200 Å), an amount of Cu from the third metal layer 63 detected is largest from the beginning of analysis (in other words, on the top surface), while an amount of Au from the fourth metal layer (Au layer) 64 detected is very small within the sputtering time of 5 minutes, even though the fourth metal layer 64 is the top surface.

This shows that Cu is diffused from the third metal layer 63 in the multilayered metal layer 6, to the top surface by radiant heat generated in formation of the second electrode (lining electrode) layer. Specifically, when the fourth metal layer (Au layer) 64 has a small thickness, Cu is diffused from the third metal layer (Cu layer) 63 to dominate the fourth metal layer 64. As a result, a forward voltage variation (3σ) is 0.141.

Moreover, Cu diffusion to the top surface deteriorates wettability of the preform material (solder) for mounting of the semiconductor chip, thereby leading to a problem of occurrence of stress concentration.

FIG. 6B shows the case where the fourth metal layer 64 has a thickness of 500 Å, which is greater than that in the case of FIG. 6A. In this case, the amount of Au detected and the amount of Cu detected are substantially the same near the top surface (within the sputtering time of 2 minutes).

Even when the thickness of the fourth metal layer 64 is 500 Å, the Cu diffusion from the third metal layer 63 is observed. As a result, a forward voltage variation (3σ) is 0.033, which is smaller than that in the case of FIG. 6A.

FIG. 6C shows the case where the fourth metal layer 64 has a thickness of 1000 Å. In this case, the amount of Au detected is the largest near the top surface (within the sputtering time of 5 minutes) and the amount of Cu detected becomes the largest after the sputtering time of 5 minutes.

Specifically, in this case, almost no Cu is diffused from the third metal layer 63 to the top surface. As a result, a forward voltage variation (3σ) is also significantly reduced to 0.003.

Furthermore, the Cu diffusion from the Cu layer to the top surface can be suppressed. Thus, it is possible to avoid stress concentration caused by deterioration in the wettability of the preform material (solder) for mounting of the semiconductor chip.

Specifically, the thickness of the fourth metal layer (Au layer) 64 is preferably 600 Å or more, more preferably, about 1000 Å.

Here, it is predicted that the Cu diffusion to the top surface is suppressed by further increasing the thickness of the fourth metal layer 64 and thus the forward voltage variation can also be reduced. However, as described above, the thickness of about 1000 Å is enough to reduce the forward voltage variation. If the thickness of the Au layer is increased more than necessary, cost is also increased. Accordingly, the thickness of the fourth metal layer 64 in this embodiment may be 600 Å or more (preferably 1000 Å). If the thickness is larger than the above, the thickness of 2000 Å or the like, for example, is accordingly selected in consideration of the cost and the like.

As described above, the variation in the resistance value is minimized by increasing the thicknesses of the first and fourth metal layers 61 and 64. Thus, the forward voltage variation can be reduced.

With reference to FIG. 4 again, description will be given of characteristics of the multilayered metal layer 6 having the first to fourth metal layers 61 to 64 laminated.

In FIG. 4, each of the wafers c and d has the multilayered metal layer 6 as an example of this embodiment. Specifically, the thickness of the first metal layer (Ti layer) 61 is 1000 Å, the thickness of the second metal layer (Ni layer) 62 is 200 Å, the thickness of the third metal layer (Cu layer) 63 is 1500 Å, and the thickness of the fourth metal layer (Au layer) 64 is 1000 Å.

Specifically, it is found out that the multilayered metal layer 6 in this embodiment has hardly any fluctuation in the forward voltage VF value before and after the temperature cycling test.

Therefore, stress in the multilayered metal layer 6 (and the first electrode layer 3) can be relaxed. Thus, it can be said that stable conditions are achieved also for stress between the connection 15 and the multilayered metal layer 6.

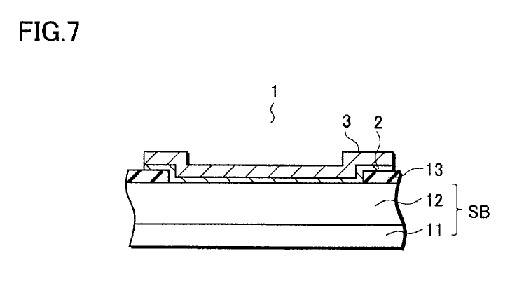

With reference to FIGS. 7 to 10, description will be given of a method for manufacturing the semiconductor device 100 according to the present invention.

The method for manufacturing a semiconductor device according to the present invention includes the steps of: forming an electrode layer on a the first principal surface of a semiconductor substrate to be a semiconductor chip; forming a first metal layer mainly made of titanium with a thickness of 400 Å to 2000 Å on the electrode layer by use of an electron impact heating deposition method; forming a second metal layer mainly made of nickel with a thickness of 100 Å to 1000 Å on the first metal layer by use of the electron impact heating deposition method; forming a third metal layer made of copper or chromium with a thickness of 500 Å to 2000 Å on the second metal layer by use of a resistance heating deposition method; forming a fourth metal layer made of gold, palladium or platinum with a thickness of 600 Å to 2000 Å on the third metal layer by use of the resistance heating deposition method; forming another electrode layer on a second principal surface of the semiconductor substrate; and fixing connection made of a metal plate above the fourth metal layer by applying a preform material thereto.

First Step (FIG. 7): forming an electrode layer on a first principal surface of a semiconductor substrate to be a semiconductor chip.

First, a semiconductor substrate SB to be a semiconductor chip is prepared. The semiconductor substrate SB has a structure, for example, in which an n− type semiconductor layer 12 is laminated on an n+ type silicon semiconductor substrate 11. On a first principal surface of the semiconductor substrate SB, an insulating film 13 is provided. Thereafter, a Schottky metal layer 2 (for example, titanium (Ti), molybdenum (Mo) or the like) is provided, which forms a Schottky junction with a surface of the n− type semiconductor layer through an opening in the insulating film 13.

Next, on the Schottky metal layer 2, the first electrode layer 3 connected thereto is provided. The first electrode layer 3 is, for example, an aluminum layer (Al layer) formed by use of a sputtering method and has a thickness of 2.5 μm, for example.

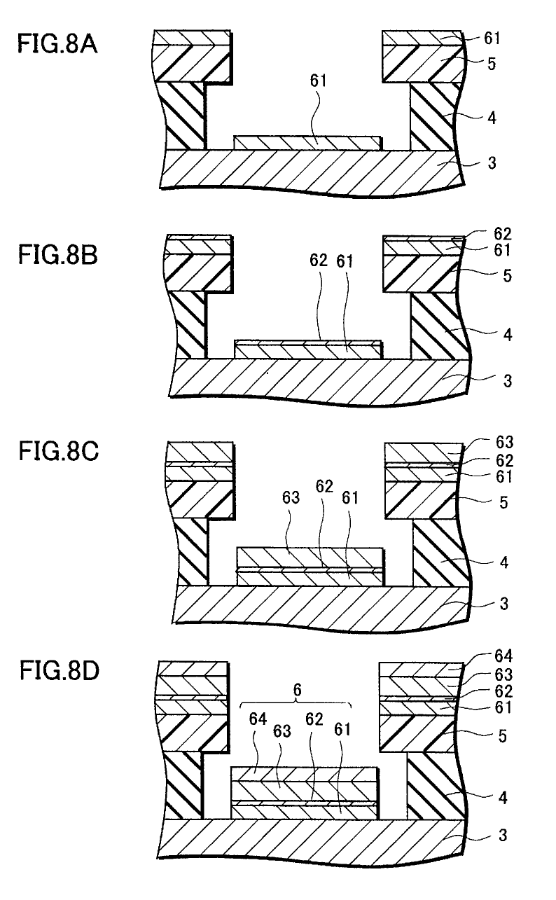

Second Step (FIG. 8A): forming a first metal layer mainly made of titanium with a thickness of 400 Å to 2000 Å on the electrode layer by use of an electron impact heating deposition method.

FIGS. 8A to 8D are enlarged cross-sectional views showing a first electrode layer 3 portion.

On the first electrode layer 3, an insulating film 4 is formed in consideration of oxidation resistance and moisture resistance of the Al layer. The insulating film 4 is, for example, a nitride film, which is deposited so as to have a thickness of about 6000 Å to 8000 Å by use of a CVD method for about 2 hours at 800° C. Thereafter, a resist 5 is provided on the insulating film 4 and an opening is provided at a desired position. Subsequently, by using the resist 5 as a mask, a part of the insulating film 4 is removed by use of a photolithography technology. The first electrode layer 3 exposed in the opening of the insulating film 4 serves as a pad portion P to be electrically connected to connection (a metal plate) in a subsequent step.

Thereafter, a first metal layer 61 which forms a multilayered metal layer is formed on the pad portion P. Specifically, while leaving the resist 5 as it is, the first metal layer 61 mainly made of titanium is formed on the entire surface by use of an electron impact heating deposition method. As the first metal layer 61, titanium (Ti (pure Ti)) or boron (B)-containing Ti is used in consideration of adhesion with the Al layer and the like. A thickness of the first metal layer 61 is 400 Å to 2000 Å and is set to, for example, 1000 Å.

Moreover, film quality of the first metal layer 61 can be improved by setting the thickness about 10 times larger than that in the conventional structure. Therefore, it is possible to avoid a variation in electrical characteristics and characteristic fluctuations in a temperature cycling test or the like in the multilayered metal layer serving as a junction part between a preform material and the first electrode layer 3.

Third Step (FIG. 8B): forming a second metal layer mainly made of nickel with a thickness of 100 Å to 1000 Å on the first metal layer by use of the electron impact heating deposition method.

On the first metal layer 61, while leaving the resist 5 as it is, the second metal layer 62 is formed in consideration of bonding properties with respect to the preform material to be applied in a subsequent step and in consideration of prevention of invasion (erosion) by the preform material.

The second metal layer 62 is a nickel (Ni (pure Ni)) layer, a phosphorus (P)-containing Ni layer or a boron (B)-containing Ni layer. The second metal layer 62 is deposited so as to have a thickness of 100 Å to 1000 Å (for example, 200 Å) by use of the electron impact heating deposition method.

Fourth Step (FIG. 8C): forming a third metal layer made of copper or chromium with a thickness of 500 Å to 2000 Å on the second metal layer by use of a resistance heating deposition method.

On the second metal layer 62, a third metal layer 63 is deposited in consideration of, for example, suppression of spread of the preform material, prevention of invasion by the preform material, improvement in the bonding properties with respect to the preform material. The third metal layer 63 is a copper (Cu) layer or a chromium (Cr) layer, which is deposited so as to have a thickness of 500 Å to 2000 Å (for example, 1500 Å) by use of a resistance heating deposition method.

The Cu layer which has poor wettability compared with the Ni layer that is the second metal layer 62 and which is likely to be eroded by the preform material (particularly, solder) is provided to have a relatively large thickness. Thus, erosion by the preform material can be limited to only around a surface of the Cu layer. Thus, it is possible to reduce influence of the preform material on the second metal layer 62.

Fifth Step (FIG. 8D): forming a fourth metal layer made of gold, palladium or platinum with a thickness of 600 Å to 2000 Å on the third metal layer by use of the resistance heating deposition method.

On the third metal layer 63, a fourth metal layer 64 is deposited in consideration of wettability of the preform material, prevention of oxidation of the third metal layer 63, and the like. The fourth metal layer 64 is a gold (Au) layer, a palladium (Pd) layer or a platinum (Pt) layer and is deposited to have a thickness of 600 Å to 2000 Å (for example, 1000 Å) by use of the resistance heating deposition method.

By forming the fourth metal layer 64 so as to have a relatively large thickness, the third metal layer (Cu layer) 63 can be prevented from being diffused into the top surface by a temperature increase (radiant heat) in a subsequent step (lining step). Thus, it is possible to avoid stress concentration caused by deterioration in the wettability of the preform material (solder) in mounting of the semiconductor chip.

Thereafter, the resist 5 and the first to fourth metal layers 61 to 64 on the resist 5 are removed at the same time by lift-off to form the multilayered metal layer 6 on the pad portion P of the first electrode layer 3.

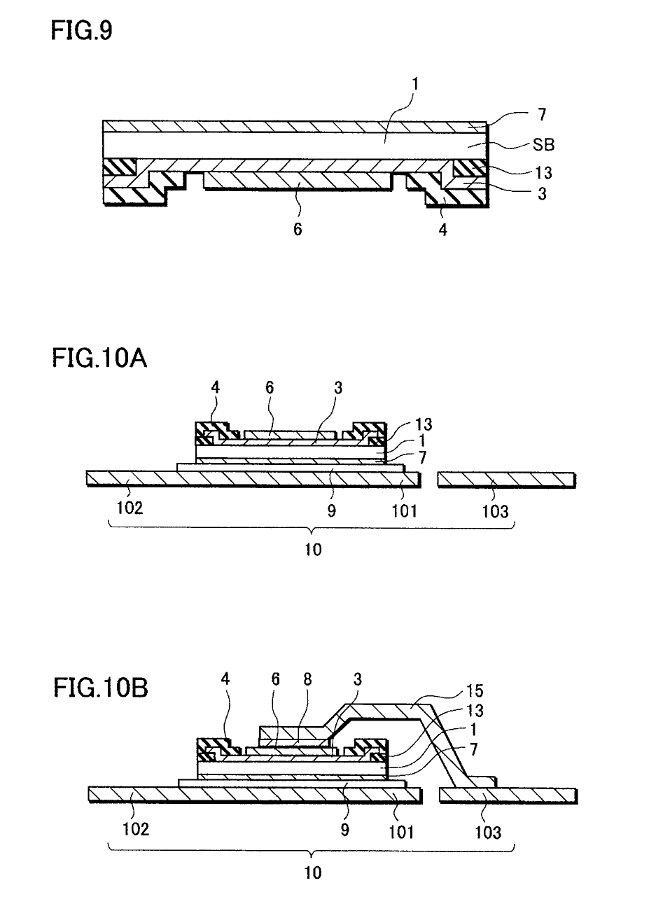

Sixth Step (FIG. 9): forming another electrode layer on a second principal surface of the semiconductor substrate.

FIG. 9 is a schematic cross-sectional view showing the semiconductor chip 1 in which the Schottky metal layer is omitted.

A second electrode (lining electrode) layer 7 is formed on a second principal surface of the semiconductor substrate. Here, the second electrode layer 7 is a cathode electrode of a SBD.

The second electrode layer 7 is formed in the following manner. First, a Ti layer with a thickness of, for example, 500 Å and a Ni layer with a thickness of, for example, 5000 Å are deposited by use of the electron impact heating deposition method. Thereafter, an Au layer with a thickness of, for example, 500 Å is deposited by use of the resistance heating deposition method.

In this event, the Cu layer in the multilayered metal layer 6 (the third metal layer 63) may be diffused by radiant heat. However, since the fourth metal layer 64 (Au layer) has a relatively large thickness in this embodiment, the diffusion of Cu up to the surface of the fourth metal layer 64 (the multilayered metal layer 6) can be prevented.

Seventh Step (FIG. 10): fixing connection made of a metal plate above the fourth metal layer by applying a preform material thereto.

As shown in FIG. 10A, the semiconductor substrate is divided into individual semiconductor chips 1 by dicing. The semiconductor chip 1 is mounted on a supporting substrate (for example, a header 101 of a lead frame) 10. The second electrode layer 7 and the header 101 are fixed by use of the preform material 9, and a lead 102 connected to the header is extended to the outside as a cathode terminal.

Moreover, as shown in FIG. 10B, the preform material 8 (for example, a lead (Pb)/tin (Sn) layer, a silver (Ag)/Sn layer, a Ag/Cu layer, a Ag/Au layer or the like) is applied to the surface of the multilayered metal layer 6 to fix the connection 15 made of a metal plate. The connection 15 is connected to a lead 103 to be an anode terminal and led to the outside.

Moreover, the connection 15 may have its end portion directly extended to serve as the anode terminal.

Thereafter, the semiconductor chip 1, the connection 15 and the lead frame 10 are integrally sealed by transfer molding using a mold and resin injection. A resin layer forms an external shape of a package. Thus, the final structure shown in FIG. 1B is obtained.

Note that, in this embodiment, description was given of the semiconductor chip 1 in the SBD as an example. However, the present invention is not limited thereto but can be similarly implemented for any semiconductor device having a wireless structure in which the semiconductor chip 1 is a MOSFET, a pn junction diode, a bipolar transistor, an IGBT or the like.

According to this embodiment, first, in the semiconductor device having the wireless structure, reliability can be improved by minimizing a variation in electrical characteristics and characteristic fluctuations in a temperature cycling test and the like.

As to minimization of the variation in electrical characteristics, for example, the forward voltage VF value in the Schottky barrier diode having a breakdown voltage of 15 V is compared with that in the conventional structure at 2.0 A. In this case, 3σ (3 times larger than the standard deviation (σ) of the variation in electrical characteristics) is reduced by 90% (down to 10%). Specifically, yield can be significantly improved by minimizing the variation in electrical characteristics.

Moreover, as to minimization of the characteristic fluctuations, the characteristic fluctuations that have occurred in the conventional structure do not occur in the temperature cycling test, for example. Thus, reliability can be significantly improved.

What is claimed is:

1. A semiconductor device comprising:
a semiconductor chip;
an electrode layer disposed on the chip;
a multilayered metal layer disposed on the electrode layer;
a connection formed of a metal plate and disposed on the multilayered metal layer; and
a layer of a preform material attaching the connection to the multilayered metal layer,
wherein the multilayered metal layer is formed by laminating a first metal layer comprising titanium and having a thickness of 400 Å to 2000 Å, a second metal layer comprising nickel and having a thickness of 100 Å to 1000 Å and a third metal layer comprising copper or chromium and having a thickness of 500 Å to 2000 Å in this order.

2. The semiconductor device of claim 1, wherein the electrode layer comprises an aluminum layer or a silicon-containing aluminum layer.

3. The semiconductor device of claim 1, wherein the first metal layer further comprises boron.

4. The semiconductor device of claim 1, wherein the second metal layer further comprises phosphorus or boron.

5. The semiconductor device of claim 1, further comprising a fourth metal layer which is part of the multilayered metal layer, disposed on the third metal layer, and comprises gold, palladium or platinum.

6. A method of manufacturing a semiconductor device, comprising:
providing a semiconductor wafer;
forming an electrode layer on a first principal surface of the wafer;
forming on the electrode layer a first metal layer comprising titanium so as to have a thickness of 400 Å to 2000 Å;
forming on the first metal layer a second metal layer comprising nickel so as to have a thickness of 100 Å to 1000 Å;
forming on the second metal layer a third metal layer comprising copper or chromium so as to have a thickness of 500 Å to 2000 Å;
forming on the third metal layer a fourth metal layer comprising gold, palladium or platinum so as to have a thickness of 600 Å to 2000 Å;
forming another electrode layer on a second principal surface of the wafer;
dicing the wafer into a plurality of chips; and
attaching a connection made of a metal plate to the fourth metal layer of one of the diced chips using a preform material.

7. The method of claim 6, wherein the first and second metal layers are formed by an electron impact heating deposition, and the third and fourth metal layers are formed by a resistance heating deposition.
